(19) United States
(12) Patent Application Publication
(10) Pub. No.: US 2025/0371233 A1
(43) Pub. Date: Dec. 4, 2025

(54) SYSTEMS AND METHODS FOR REAL-NUMBER SYSTEM VERILOG MODEL OF MOSFET FOR ACCELERATED MIXED-SIGNAL FUNCTIONAL VERIFICATION

(71) Applicant: SILICONCH SYSTEMS PVT LTD, Karnataka (IN)

(72) Inventors: Kaustubh KUMAR, Uttar Pradesh (IN); Sirisha MUNNANGI, Andhra Pradesh (IN); Sachin BALLIHITALU SATEESHA, Karnataka (IN); Ashrith NERELAGERE MEGHARAJ, Bengaluru (IN)

(21) Appl. No.: 18/816,819

(22) Filed: Aug. 27, 2024

(30) Foreign Application Priority Data
May 29, 2024 (IN) 202441041611

(51) Int. Cl. G06F 30/3323; G06F 30/3315

(52) U.S. Cl. CPC G06F 30/3323; G06F 30/3315

(57) ABSTRACT

The present disclosure relates to a computer-implemented method (200) and a system (100) for implementing a real-number System Verilog model of a Metal-Oxide-Semiconductor Field-Effect Transistor (MOSFET) for accelerated mixed-signal functional verification. The method (200) includes establishing (202) an Analog net including a Thevenin voltage and a Thevenin resistance at drain, source, and gate terminals of the MOSFET, and extracting (204) effective voltages and effective resistances from the drain, source, and gate terminals of the MOSFET. The method (200) includes establishing (206) a fast quadratic solver to compute drain to source MOSFET current, drain to source MOSFET voltage, and drain to source MOSFET resistance. The method (200) includes driving (208) feedback of the drain to source MOSFET current in terms of a drive voltage and a drive resistance to the Analog net, and attaining (210) a circuit convergence in real-time through an event-driven mechanism at a particular timestamp.

### CROSS REFERENCE TO RELATED APPLICATIONS

The present application is based on and claims priority to Indian Patent Application number 20244041611, filed on May 29, 2024, the entire contents of which is herein incorporated by reference.

### TECHNICAL FIELD

The present disclosure relates generally to the field of mixed signal electronic design automation. In particular, the present disclosure relates to a method and a system for implementing a real-number System Verilog model of a Metal-Oxide-Semiconductor Field-Effect Transistor (MOSFET) for accelerated mixed-signal functional verification.

### BACKGROUND

Background description includes information that may be useful in understanding the present disclosure. It is not an admission that any of the information provided herein is prior art or relevant to the presently claimed disclosure, or that any publication specifically or implicitly referenced is prior art.

A MOSFET is a type of transistor commonly used in integrated circuits. In order to simulate a behaviour of the MOSFET in the mixed signal simulations, modelling languages such as Verilog-A and Verilog-AMS may be used. These languages use Analog behavioural constructs to simulate the device behaviour in an Analog domain by solving Kirchoff's laws and device equations at discrete time intervals.

In order to run these simulations, a Simulation Program with Integrated Circuit Emphasis (SPICE) simulators may be utilized. The SPICE simulators solve complex differential equations that govern the behaviour of the integrated circuits by considering the physical parameters of the integrated circuit, such as resistance, capacitance, and inductance. This may require a significant amount of computation, which can increase a simulation time.

The existing real-number based models of MOSFETs may face challenges like limited applicability and may experience convergence issues when used in system-level circuits. This means that the simulated results may not accurately reflect the behaviour of the actual circuit. Many techniques have been evolved to obviate the above-mentioned issues, for instance, conventional behavioural real-number models use nodal voltage analysis to iterate and converge. Further, the conventional models (for e.g., EEnet based models) may face convergence issues with large transients, and may fail to find operating points in a system level in few special cases.

There is, therefore, a need for an improved system and a method for implementing a real-number System Verilog model of the MOSFET for accelerated mixed-signal functional verification by overcoming the deficiencies of the prior art.

### Objects of the Present Disclosure

Some of the objects of the present disclosure, which at least one embodiment herein satisfies are listed herein below.

An object of the present disclosure is to provide a system and a method for efficiently implementing a real-number System Verilog model of a MOSFET for accelerated mixed-signal functional verification.

Another object of the present disclosure is to establish an Analog net including a Thevenin voltage and a Thevenin resistance at drain, source, and gate terminals of a MOSFET.

Another object of the present disclosure is to compute drain to source MOSFET current, drain to source MOSFET voltage, and drain to source MOSFET resistance by extracting effective voltages and effective resistances from the drain, source, and gate terminals of the MOSFET.

Another object of the present disclosure is to drive feedback of the drain to source MOSFET current in terms of a drive voltage and a drive resistance to the Analog net.

Yet another object of the present disclosure is to attain a circuit convergence in real-time through an event-driven mechanism at a particular timestamp.

The other objects and advantages of the present disclosure will be apparent from the following description when read in conjunction with the accompanying drawings, which are incorporated for illustration of the preferred embodiments of the present disclosure and are not intended to limit the scope thereof.

### SUMMARY

The present disclosure relates generally to the field of robust and bug-free mixed signal electronic design automation. In particular, the present disclosure relates to a method and a system for implementing a real-number System Verilog model of a MOSFET for accelerated mixed-signal functional verification.

In an aspect, the present disclosure relates to a computer-implemented method for implementing a real-number System Verilog model of a MOSFET for accelerated mixed-signal functional verification. The method includes establishing, by a system, an Analog net including a Thevenin voltage and a Thevenin resistance at drain, source, and gate terminals of the MOSFET. The method includes extracting, by the system, effective voltages and effective resistances from the drain, source, and gate terminals of the MOSFET. The method includes establishing, by the system, a fast quadratic solver to compute drain to source MOSFET current, drain to source MOSFET voltage, and drain to source MOSFET resistance based on the extraction. Further, the method includes driving, by the system, feedback of the drain to source MOSFET current in terms of a drive voltage and a drive resistance to the Analog net, and attaining, by the system, a circuit convergence in real-time through an event-driven mechanism at a particular timestamp.

In an embodiment, establishing, by the system, the Analog net including the Thevenin voltage and the Thevenin resistance at the drain, source, and gate terminals of the MOSFET may include implementing the Analog net by implementing a user defined net-type and user defined resolution function for evaluation of the Thevenin voltage and the Thevenin resistance at the drain, source, and gate terminals of the MOSFET, and interconnecting each of the drain, source, and gate terminals of the MOSFET to other MOSFETs and electrical components.

In an embodiment, extracting, by the system, the effective voltages and the effective resistances from the drain, source, and gate terminals of the MOSFET may include evaluating the effective voltages and the effective resistances driven by external drivers at the drain, source, and gate terminals of the MOSFET by implementing Thevenin equations and the drive voltage and the drive resistance driven to the Analog net from the MOSFET, and determining that the effective voltages and the effective resistances driven by external drivers at the drain, source, and gate terminals of the MOSFET is within specified voltage and resistance tolerances.

In an embodiment, in response to computing the drain to source MOSFET current, the drain to source MOSFET voltage, and the drain to source MOSFET resistance, the method may include computing nodal voltages at the drain, source and gate terminals of the MOSFET for the computed effective voltages and the drain to source MOSFET current by calculating a drain to source voltage and a gate to source voltage for the drain to source MOSFET current. The drain to source MOSFET current may be assumed zero at a first iteration of a first time-step.

In an embodiment, the method may include computing, by the system, the drain to source MOSFET current in presently satisfied regions of operation of the MOSFET, based on the calculated drain to source voltage and the gate to source voltage of the MOSFET, by calculating roots of a Quadratic equation for a selected region of operation of the MOSFET. The Quadratic equation may be formulated by implementing a Kirchoff's voltage law, a current law, and a drain to source MOSFET current equation for the selected region of operation of the MOSFET.

In an embodiment, the method may include computing, by the system, a drain to source and gate to source MOSFET voltage using the calculated roots of the Quadratic equations, and re-validating the selected region of operation of the MOSFET by checking MOSFET operating region conditions, to select an appropriate drain to source MOSFET current from the two roots of the Quadratic equation.

In an embodiment, the method may include evaluating, by the system, the drain to source MOSFET current in other regions of operation if the calculated drain to source MOSFET current fails to satisfy previously satisfied MOSFET operating region conditions.

In an embodiment, the method may include evaluating, by the system, a MOSFET body diode current if the evaluated region of operation is cutoff using numerical iterative approximations including diode equations.

In an embodiment, driving, by the system, the feedback of drain to source MOSFET current in terms of the drive voltage and the drive resistance to the Analog net may include determining an effective drain to source MOSFET resistance using the drain to source MOSFET current and the drain to source MOSFET voltage; and determining drive voltages and drive resistances for each of the drain, source, and gate terminals of the MOSFET using the effective drain to source MOSFET resistance, and effective voltage and resistance of external drivers at other terminals of the MOSFET.

In an embodiment, attaining, by the system, the circuit convergence in real-time may include re-adjusting, by the system, using the event-driven mechanism, the drain to source MOSFET current, the drain to source MOSFET voltage, and the drain to source MOSFET resistance dynamically based on a change in the Thevenin voltage and the Thevenin resistance at the drain, source and gate terminals of the MOSFET in real-time at the particular timestamp.

In an embodiment, the method may include evaluating, by the system, a fast quadratic method by specifying voltage and resistance tolerances for the effective voltage and the effective resistance driven by the external drivers at the drain, source, and gate terminals of the MOSFET to avoid convergence issues over minute driver variations in the particular timestamp.

In an embodiment, the MOSFET may be one of an n-type MOSFET or a p-type MOSFET.

In an embodiment, the method may include configuring, by the system, the MOSFET when the drain and gate terminals of the MOSFET are shorted.

In an aspect, the present disclosure relates to a system for implementing a real-number System Verilog model of a MOSFET for accelerated mixed-signal functional verification. The system includes a processor, and a memory operatively coupled to the processor. The memory includes processor-executable instructions which, when executed by the processor, cause the processor to establish an Analog net including a Thevenin voltage and a Thevenin resistance at drain, source, and gate terminals of the MOSFET. The processor extracts effective voltages and effective resistances from the drain, source, and gate terminals of the MOSFET by external drivers. The processor computes drain to source MOSFET current, drain to source MOSFET voltage, and drain to source MOSFET resistance based on the extraction. The processor drives feedback of drain to source MOSFET current in terms of a drive voltage and a drive resistance to the Analog net, and attains a circuit convergence in real-time through an event-driven mechanism at a particular timestamp.

In an embodiment, the Analog net may be established as an interconnection between a plurality of system components of an electrical circuit and the MOSFET.

In an embodiment, the processor may compute the drain to source MOSFET current, the drain to source MOSFET voltage, and the drain to source MOSFET resistance using a fast quadratic solver.

In an embodiment, the feedback of the drain to source MOSFET current may be driven in terms of the drive voltage and the drive resistance to the Analog net by satisfying Kirchoff's voltage and current laws in an electrical system.

In an embodiment, the processor may be configured to evaluate a driver strength at the drain, source, and gate terminals of the MOSFET beyond a specified tolerance range.

Various objects, features, aspects, and advantages of the inventive subject matter will become more apparent from the following detailed description of preferred embodiments, along with the accompanying drawing figures in which like numerals represent like components.

### BRIEF DESCRIPTION OF THE DRAWINGS

The following drawings form part of the present specification and are included to further illustrate aspects of the present disclosure. The disclosure may be better understood by reference to the drawings in combination with the detailed description of the specific embodiments presented herein.

FIG. 1 illustrates an example block diagram of a system for implementing a real-number System Verilog model of a MOSFET for accelerated mixed-signal functional verification, in accordance with an embodiment of the present disclosure.

FIG. 2 illustrates a top-level flow chart (200) for implementing a real-number System Verilog model of a MOSFET for accelerated mixed-signal functional verification, in accordance with an embodiment of the present disclosure.

FIG. 3 illustrates a flow chart depicting an evaluation flow of a MOSFET model, in accordance with an embodiment of the present disclosure.

FIG. 4 illustrates a flow chart depicting a process for determining a region of operation of a MOSFET by implementing a fast quadratic solver, in accordance with an embodiment of the present disclosure.

FIG. 5 illustrates a schematic representation depicting a MOSFET model, in accordance with an embodiment of the present disclosure.

### DETAILED DESCRIPTION

The following is a detailed description of embodiments of the disclosure depicted in the accompanying drawings. The embodiments are in such detail as to clearly communicate the disclosure. If the specification states a component or feature “may,” “can,” “could,” or “might” be included or have a characteristic, that particular component or feature is not required to be included or have the characteristic.

As used in the description herein and throughout the claims that follow, the meaning of “a,” “an,” and “the” includes plural reference unless the context clearly dictates otherwise. Also, as used in the description herein, the meaning of “in” includes “in” and “on” unless the context clearly dictates otherwise.

The present disclosure relates generally to the field of mixed signal electronic design automation. In particular, the present disclosure relates to a method and a system for implementing a real-number System Verilog model of a MOSFET for accelerated mixed-signal functional verification.

In an aspect, the present disclosure relates to a computer-implemented method for implementing a real-number System Verilog model of a MOSFET for accelerated mixed-signal functional verification. The method includes establishing, by a system, an Analog net including a Thevenin voltage and a Thevenin resistance at drain, source, and gate terminals of the MOSFET. The method includes extracting, by the system, effective voltages and effective resistances from the drain, source, and gate terminals of the MOSFET. The method includes computing, by the system, drain to source MOSFET current, drain to source MOSFET voltage, and drain to source MOSFET resistance based on the extraction. Further, the method includes driving, by the system, feedback of the drain to source MOSFET current in terms of a drive voltage and a drive resistance to the Analog net, and attaining, by the system, a circuit convergence in real-time through an event-driven mechanism at a particular timestamp.

In an aspect, the present disclosure relates to a system for implementing a real-number System Verilog model of a MOSFET for accelerated mixed-signal functional verification. The system includes a processor, and a memory operatively coupled to the processor. The memory includes processor-executable instructions which, when executed by the processor, cause the processor to establish an Analog net including a Thevenin voltage and a Thevenin resistance at drain, source, and gate terminals of the MOSFET. The processor extracts effective voltages and effective resistances from the drain, source, and gate terminals of the MOSFET by external drivers. The processor computes drain to source MOSFET current, drain to source MOSFET voltage, and drain to source MOSFET resistance based on the extraction. The processor drives feedback of drain to source MOSFET current in terms of a drive voltage and a drive resistance to the Analog net, and attains a circuit convergence in real-time through an event-driven mechanism at a particular timestamp.

The description of terms and features related to the present disclosure shall be clear from the embodiments that are illustrated and described; however, the present disclosure is not limited to these embodiments only. Numerous modifications, changes, variations, substitutions, and equivalents of the embodiments are possible within the scope of the present disclosure. Additionally, the present disclosure can include other embodiments that are within the scope of the claims but are not described in detail with respect to the following description.

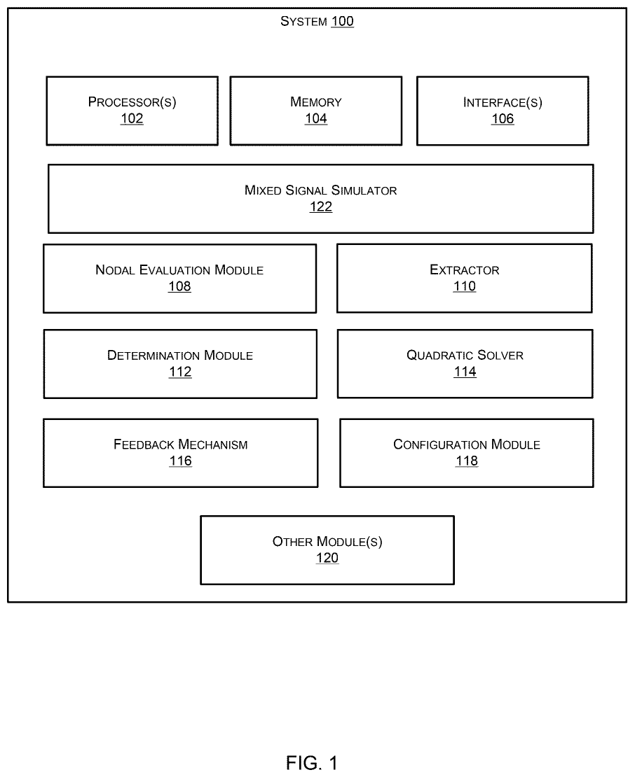

Various embodiments of the present disclosure will be explained in detail with reference to FIGS. 1-5.

FIG. 1 illustrates an example block diagram of a system (100) for implementing a real-number System Verilog model of a MOSFET for accelerated mixed-signal functional verification, in accordance with an embodiment of the present disclosure.

With reference to FIG. 1, the system (100) may include one or more processors (102). The one or more processors (102) may be implemented as one or more microcomputers, microcontrollers, edge or fog microcontrollers, digital signal MCUs, central processing units, logic circuitries, and/or any devices that process data based on operational instructions. Among other capabilities, the one or more processors (102) may be configured to fetch and execute computer-readable instructions stored in a memory (104) of the system (100). The memory (104) may be configured to store one or more computer-readable instructions or routines in a non-transitory computer-readable storage medium, which may be fetched and executed to create or share data packets over a network service. The memory (104) may include any non-transitory storage device including, for example, a volatile memory such as a Random-Access Memory (RAM), or a non-volatile memory such as an Erasable Programmable Read-Only Memory (EPROM), a flash memory, and the like.

In an embodiment, the system (100) may include an interface(s) (106). The interface(s) (106) may include a variety of interfaces, for example, interfaces for data input and output devices, referred to as I/O devices, storage devices, and the like. The interface(s) (106) may facilitate communication of the system (100). The interface(s) (106) may also provide a communication pathway for one or more components of the system (100).

In an embodiment, the one or more processors (102) may perform different functions in the system (100) using one or more modules which include, but not limited to, a nodal evaluation module (108), an extractor (110), a determination module (112), a quadratic solver (114), a feedback mechanism (116), a configuration module (118), and other module(s) (120).

In an embodiment, the system (100) may include a mixed signal simulator (122). The mixed signal simulator (122) may be configured to simulate and analyse circuits that contain both analog and digital components. The mixed signal simulator (122) may handle an interaction between analog and digital signals within the circuit. The mixed signal simulator (122) may be used for verifying correctness of mixed-signal designs before building physical prototypes, thereby identifying and fixing issues early in the design process. The mixed signal simulator (122) may be configured to optimize the design by allowing iterative testing and refinement of the circuit, thereby leading to improved performance, reduced power consumption, and better overall efficiency.

In an embodiment, the nodal evaluation module (108) may establish a custom System-Verilog construct called as an “Analog net” to calculate a Thevenin equivalent voltage and a Thevenin equivalent resistance at drain, source, and gate terminals of MOSFETs, as well as at all electrical nodes within the system (100). The Analog net may serve as an interconnection between the drain, source, and gate terminals of the MOSFET and other electrical components or MOSFETs in the system (100). The effective voltage, current, and resistances driven by each electrical component may be called as a driver to the Analog net. The Analog net may calculate the Thevenin equivalent voltage and the Thevenin equivalent resistance by considering the contributions from all connected components. The following equations (1)-(4) represent the method of calculating the Thevenin equivalent voltage and the Thevenin equivalent resistance at each electrical node of the system (100).
I. Equivalent current Iₜₕ, which is equivalent to Norton's current may be determined as:

$${I}_{th} = {\sum }_{i = 1}^{n} ( \frac{V [ i ]}{R [ i ]} + I [ i ] ) \qquad ( 1 )$$

II. Thevenin's Conductance Gₜₕ may be calculated as:

$${G}_{th} = {\sum }_{i = 1}^{n} \frac{1}{R [ i ]} \qquad ( 2 )$$

III. Thevenin's Resistance Rₜₕ may be calculated as:

$${R}_{th} = \frac{1}{{G}_{th}} \qquad ( 3 )$$

IV. Thevenin's Voltage Vₜₕ may be calculated as:

$${V}_{th} = {I}_{th} \cdot {R}_{th} \qquad ( 4 )$$

where, V[i] is a driver voltage, R[i] is a driver impedance, I[i] is a driver current, and n is a number of drivers.

Further, the Analog net may be implemented using a User Defined Nettype (UDN) which includes a User Defined Resolution function (UDF) defined in System Verilog Language Reference Manual (LRM). The UDF may call itself whenever there is a change in a driver strength, and may recompute the Thevenin voltage and the Thevenin resistances. Therefore, ensuring that the Analog Net dynamically updates the Thevenin voltage and the Thevenin resistances in response to the changes in the connected drivers.

In an embodiment, the extractor (110) may be configured for extracting effective voltages and effective resistances from the drain, source, and gate terminals of the MOSFET. The drain, source, and gate terminals of the MOSFET may be defined as in-out ports with a datatype as the Analog net representing an electrical net. The Thevenin voltage Vₜₕ and the Thevenin Resistance Rₜₕ may be accessed through the Analog Net, and effective drivers on each terminal of the MOSFET may be calculated based on feedback drivers in previous iteration. By the feedback drivers, the effective voltages and the effective resistances may be driven by the MOSFET on to the Analog net at the drain, source, and gate terminals of the MOSFET. The feedback voltage driver from the MOSFET driven onto the Analog net may be denoted as V_{cross}, and resistor driver may be denoted as R_{cross}. The effective voltages and the effective resistances driven by the external drivers at the drain, source, and gate terminals of the MOSFET may be within specified voltage and resistance tolerances.

The following equations may represent the driver at one of the nodes of the MOSFET using the Thevenin's voltage and resistance values at the respective node of the MOSFET along with the feedback driver values driven by the MOSFET. The below equations (5) and (6) may be used to extract the effective drivers on the drain, source, and gate nodes.

$${V}_{eff} = \frac{{V}_{th} \cdot {R}_{cross} - {V}_{cross} \cdot {R}_{th}}{{R}_{cross} - {R}_{th}} \qquad ( 5 )$$

$${R}_{eff} = \frac{{R}_{th} \cdot {R}_{cross}}{{R}_{cross} - {R}_{th}} \qquad ( 6 )$$

where, V_{eff} is the effective driver voltage seen from the MOSFET, R_{eff} is the effective driver resistance seen from the MOSFET, V_{cross} is the effective voltage driven by the MOSFET, and R_{cross} is the effective resistance driven by the MOSFET.

In an embodiment, the determination module (112) may be configured to determine drain to source MOSFET current, drain to source MOSFET voltage, and drain to source MOSFET resistance based on the extraction of the effective voltages and effective resistances from the drain, source, and gate terminals of the MOSFET. The determination module (112) may be configured to determine an operating point of the MOSFET, by satisfying Kirchoff's Voltage and Current Laws and MOSFET equations. The operating point of the MOSFET may be calculated using the following equations.

$${V}_{d \_ eff} - {I}_{d} \cdot ( {R}_{d \_ eff} + {R}_{s \_ eff} ) - {V}_{ds} - {V}_{s \_ eff} = 0 \qquad ( 7 )$$

where, V_{d_eff} is the effective driver voltage at the drain terminal, R_{d_eff} is the effective driver impedance at the drain terminal, V_{s_eff} is the effective driver voltage at the source terminal, R_{s_eff} is the effective driver impedance at the source terminal, V_{ds} is a voltage drop between the drain terminal and the source terminal, and I_{d} is the drain to source MOSFET current.

The drain to source MOSFET current I_{d} at a saturation region, a linear region, and a cutoff region may be defined by the following equations (8)-(10), respectively:

$${I}_{d} = ( K / 2 ) \cdot {( {V}_{gs} - {V}_{th} )}^{2} , if {V}_{ds} \geq {V}_{gs} - {V}_{th} , {V}_{gs} > {V}_{th} \qquad ( 8 )$$

$${I}_{d} = K \cdot ( {V}_{gs} - {V}_{th} - \frac{{V}_{ds}}{2} ) \cdot {V}_{ds} , if {V}_{ds} < {V}_{gs} - {V}_{th} , {V}_{gs} > {V}_{th} \qquad ( 9 )$$

$${I}_{d} = {I}_{cutoff} , if {V}_{gs} < {V}_{th} \qquad ( 10 )$$

By substituting (8)-(10) in (7), quadratic equations which satisfy both Kirchoff's Laws and MOSFET equations may be obtained to calculate the operating point of the MOSFET.

In an embodiment, the system (100) may include a quadratic solver (114). The quadratic solver (114) may be configured to compute the drain to source MOSFET current, the drain to source MOSFET voltage, and the drain to source MOSFET resistance. Depending on the region of operation or the operating point of the MOSFET, the quadratic solver (114) may calculate roots of the quadratic equations. The roots of the quadratic equations may be defined as:

$$x = \frac{- b \pm \sqrt{{b}^{2} - 4 ac}}{2 a} \qquad ( 11 )$$

Considering that the drain and gate terminals are at different voltages, at the saturation region, a, b, and c in the above equation (11) may be defined as:

$$a = \frac{K \cdot {R}_{s - eff} {R}_{s - eff}}{2} \qquad ( 12 )$$

$$b = ( - sign \cdot K \cdot ( {V}_{g \_ eff} - ( sign \cdot {V}_{th} ) - {V}_{s \_ eff} ) \cdot {R}_{s \_ eff} - 1 \qquad ( 13 )$$

$$c = \frac{K \cdot {( {V}_{g \_ eff} - ( sign \cdot {V}_{th} ) - {V}_{s \_ eff} )}^{2}}{2} \qquad ( 14 )$$

Considering that the drain and gate terminals are shorted, at the saturation region, a, b, and c in the above equation (11) may be defined as:

$$a = \frac{K \cdot {( {R}_{d \_ eff} + {R}_{s \_ eff} )}^{2}}{2} \qquad ( 15 )$$

$$b = - K \cdot ( sign \cdot ( {V}_{d \_ eff} - ( sign \cdot {V}_{th} ) - {V}_{s \_ eff} ) ) \cdot ( {R}_{d \_ eff} - {R}_{s \_ eff} ) - 1 \qquad ( 16 )$$

$$c = \frac{K \cdot ( {V}_{d \_ eff} - {( ( sign \cdot {V}_{th} ) - {V}_{s \_ eff} )}^{2}}{2} \qquad ( 17 )$$

Considering that the drain and gate terminals are at different voltages, at the linear region, a, b, and c in the above equation (11) may be defined as:

$$a = \frac{K \cdot ( {R}_{d \_ eff} + {R}_{s \_ eff} ) \cdot ( {R}_{s \_ eff} + {R}_{d \_ eff} )}{2} \qquad ( 18 )$$

$$b = ( sign ) \cdot ( K \cdot ( {V}_{d \_ eff} \cdot {R}_{d \_ eff} + {V}_{s \_ eff} \cdot {R}_{s \_ eff} - ( {V}_{g} - ( sign \cdot {V}_{th} ) ) \cdot ( {R}_{d \_ eff} + {R}_{s \_ eff} ) ) ) - 1 \qquad ( 19 )$$

$$c = K \cdot ( sign \cdot ( {V}_{d \_ eff} - {V}_{s \_ eff} ) ) \cdot ( sign \cdot ( ( {V}_{g} - ( sign \cdot {V}_{th} ) ) - \frac{( {V}_{d \_ eff} + {V}_{s \_ eff} )}{2.} ) ) \qquad ( 20 )$$

In the cutoff region, the current in the MOSFET may be calculated using the diode equations stated below:

$${I}_{d} = {I}_{o} \cdot ( {e}^{\frac{{V}_{diode}}{{V}_{temp}}} - 1 ) , if ( sign ) \cdot ( {V}_{s \_ eff} + {V}_{d \_ eff} ) > {V}_{db} \qquad ( 21 )$$

$${I}_{d} = ( sign ) \cdot \frac{( {V}_{d \_ eff} + {V}_{s \_ eff} )}{{R}_{s \_ eff} + {R}_{d \_ eff} + {R}_{ds}} , if ( sign ) \cdot ( {V}_{s \_ eff} - {V}_{d \_ eff} ) < {V}_{bd} \qquad ( 22 )$$

where, V_{diode} is a voltage drop across the body diode of the MOSFET, Vₜₑₘₚ is a thermal voltage of the body diode of the MOSFET, and R_{ds} is a Drain to Source MOSFET resistance and in the above equation it corresponds to high impedance.

The “sign” term in the above equations denotes sign reversal for the n-channel and p-channel. The value of “sign” is “1” for n-channel MOSFET and “−1” for p-channel MOSFET, usually this parameter may be set by a user. Hence the above set of equations is universal to both P-MOSFET and N-MOSFET.

Initially, the MOSFET may be assumed to be in the saturation region and the respective quadratic expression may be solved to obtain two roots which represent the drain to source MOSFET currents ID1 and ID2 as solution. Saturation region conditions may be validated by calculating V_{ds} (drain to source MOSFET voltage) and V_{gs} (Gate to Source MOSFET Voltage) with respect to new roots ID1 and ID2. The root satisfying the operating region of the MOSFET may be determined as the current ID (drain to source MOSFET current).

If both the roots fail to satisfy saturation region, the MOSFET may be assumed to be in the linear region, and respective quadratic expression may be evaluated and the roots ID1 and ID2 may be obtained. Linear region conditions may be validated by calculating the V_{ds}, and the V_{gs} with respect to new roots ID1 and ID2. The root satisfying the operating region of the MOSFET may be determined as the current ID. The equations for V_{ds}, and the V_{gs} are as follows:

$${V}_{ds} = ( sign ) \cdot ( {V}_{d \_ eff} + {V}_{s \_ eff} ) - {I}_{d} \cdot ( {R}_{d \_ eff} + {R}_{s \_ eff} ) \qquad ( 23 )$$

$${V}_{gs} = ( sign ) \cdot ( {V}_{g \_ eff} + {V}_{s \_ eff} ) - {I}_{d} \cdot {R}_{s \_ eff} \qquad ( 24 )$$

If the calculated roots fail to satisfy both regions i.e., the saturation region and the linear region, the MOSFET region may be determined as the cutoff region. In this case, body diode expression may be evaluated and the ID in the cutoff region may be evaluated.

The internal resistance for the MOSFET i.e., the drain to source MOSFET resistance R_{ds} may be defined to balance the Kirchoff's voltage law based on the determined current ID and V_{ds}. R_{ds} may be defined as:

$${R}_{d s} = \frac{( sign ) \cdot ( {V}_{d \_ eff} + {V}_{s \_ eff} ) - {I}_{d} \cdot ( {R}_{s \_ eff} + {R}_{d \_ eff} )}{{I}_{d}} \qquad ( 25 )$$

In an embodiment, the system (100) may include a feedback mechanism (116) configured to drive the feedback of the drain to source MOSFET current in terms of the drive voltage and the drive resistance to the Analog net. The feedback drivers from the MOSFET onto the Analog net at the drain, source, and gate terminals of the MOSFET may be evaluated using effective resistances and effective voltages by considering all calculated V_{eff} and R_{eff} from the Analog net, where,

$${V}_{d \_ cross} = {V}_{s \_ eff} \qquad ( 26 )$$

$${R}_{{d}_{-} cross} = {R}_{{s}_{-} eff} + {R}_{ds} \qquad ( 27 )$$

$${V}_{{s}_{-} cross} = {V}_{{d}_{-} eff} \qquad ( 28 )$$

$${R}_{{s}_{-} cross} = {R}_{{d}_{-} eff} + {R}_{ds} \qquad ( 29 )$$

The V_{cross} and R_{cross} may be driven to each Analog net. The function in each Analog net may recompute the Thevenin resistance Rₜₕ and the Thevenin voltage Vₜₕ. An event-based construct may be triggered whenever the driver strength varies and recomputes ID. Voltage and resistance tolerance levels may be defined to avoid possible convergence issues for very small driver variations.

In an embodiment, the system (100) may include a configuration module (118) for configuring the MOSFET when the drain and gate terminals of the MOSFET are shorted. There are two sets of equations present for the MOSFET operating in the saturation region. The first set of equations (12)-(14) represents the MOSFET under the saturation region with different nodal voltages at the gate and drain terminals. The second set of equations (15)-(17) represents the MOSFET when both the gate and drain terminals are at the same nodal voltages, in this configuration, the MOSFET may act as a diode-connected device. Here, V_{ds}=V_{gs}, hence the MOSFET enters the saturation region when V_{gs}>Vₜₕ else lies in the cutoff region. This may be configured through a parameterized input to the behavioural model. The type of the MOSFET i.e., P-MOSFET or N-MOSFET may be configured through parameterized input to the behavioural model.

In an embodiment, the system (100) may include other modules (120) which may individually or combinedly function with the other above-mentioned modules/components to attain a circuit convergence in real-time through the event-driven mechanism at a particular timestamp.

Although FIG. 1 shows an exemplary block diagram of the system (100), in other embodiments, the system (100) may include fewer components, different components, differently arranged components, or additional functional components than depicted in FIG. 1. Additionally, or alternatively, one or more components of the system (100) may perform functions described as being performed by one or more other components of the system (100).

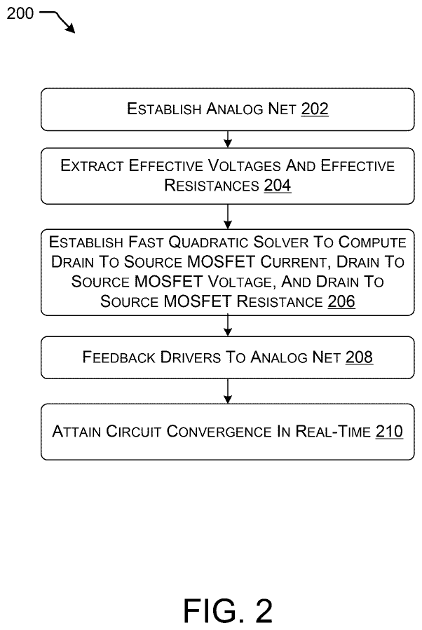

FIG. 2 illustrates a top-level flow chart (200) for implementing a real-number System Verilog model of a MOSFET for accelerated mixed-signal functional verification, in accordance with an embodiment of the present disclosure.

With reference to FIG. 2, at 202, the method (200) may include establishing an Analog net including a Thevenin voltage and a Thevenin resistance at drain, source, and gate terminals of the MOSFET. The Analog net may be established using a user defined net-type and user defined resolution function for evaluation of the Thevenin voltage and the Thevenin resistance at the drain, source, and gate terminals of the MOSFET. The Analog net may be established by interconnecting each of the drain, source, and gate terminals of the MOSFET to other MOSFETs and electrical components of the system (100), as illustrated in FIG. 1.

At 204, the method (200) may include extracting effective voltages and effective resistances from the drain, source, and gate terminals of the MOSFET. The extraction of the effective voltages and effective resistances from the drain, source, and gate terminals of the MOSFET may include evaluating the effective voltages and the effective resistances driven by external drivers at the drain, source, and gate terminals of the MOSFET using Thevenin equations, and the drive voltage and the drive resistance driven to the Analog net from the MOSFET. The effective voltages and the effective resistances driven by the external drivers at the drain, source, and gate terminals of the MOSFET may be within specified voltage and resistance tolerances.

At 206, the method (200) may include establishing a fast quadratic solver to compute drain to source MOSFET current, drain to source MOSFET voltage, and drain to source MOSFET resistance based on the extraction of the effective voltages and effective resistances from the drain, source, and gate terminals of the MOSFET. In response to computing the drain to source MOSFET current, the drain to source MOSFET voltage, and the drain to source MOSFET resistance, the method (200) may include computing nodal voltages at the drain, source, and gate terminals of the MOSFET for the computed effective voltages and the drain to source MOSFET current. The nodal voltages may be computed by calculating a drain to source voltage and a gate to source voltage for the drain to source MOSFET current. The drain to source MOSFET current may be assumed zero at a first iteration of a first time-step.

In an embodiment, the drain to source MOSFET current in presently satisfied regions of operation of the MOSFET may be computed, based on the calculated drain to source voltage and the gate to source voltage of the MOSFET. The drain to source MOSFET current may be computed by calculating roots of a quadratic equation for a selected region of operation of the MOSFET. The quadratic equation may be formulated by using a Kirchoff's voltage law, a current law, and a drain to source MOSFET current equation for the selected region of operation of the MOSFET.

In an embodiment, the drain to source MOSFET voltage and the gate to source MOSFET voltage may be computed using the calculated roots of the quadratic equations. Further, the method (200) may include re-validating the selected region of operation of the MOSFET by checking MOSFET operating region conditions, to select an appropriate drain to source MOSFET current from the two roots of the quadratic equation.

In an embodiment, the method (200) may include evaluating the drain to source MOSFET current in other regions of operation if the calculated drain to source MOSFET current fails to satisfy previously satisfied MOSFET operating region conditions. In an embodiment, the method (200) may include evaluating a MOSFET body diode current if the evaluated region of operation is a cutoff region, using numerical iterative approximations including diode equations.

At 208, the method (200) may include driving feedback of the drain to source MOSFET current in terms of a drive voltage and a drive resistance to the Analog net. The feedback drivers from the MOSFET onto the Analog net may be performed by determining an effective drain to source MOSFET resistance using the drain to source MOSFET current and the drain to source MOSFET voltage. Further, the feedback drivers from the MOSFET onto the Analog net may be performed by determining the drive voltages and the drive resistances for each of the drain, source, and gate terminals of the MOSFET using the effective drain to source MOSFET resistance, and the effective voltage and resistance of the external drivers at other terminals of the MOSFET.

At 210, the method (200) may include attaining, by the system, a circuit convergence in real-time through an event-driven mechanism at a particular timestamp. The circuit convergence may be attained by re-adjusting, using the event-driven mechanism, the drain to source MOSFET current, the drain to source MOSFET voltage, and the drain to source MOSFET resistance dynamically based on a change in the Thevenin voltage and the Thevenin resistance at the drain, source and gate terminals of the MOSFET in real-time at the particular timestamp.

In an embodiment, a fast quadratic method may be evaluated by specifying voltage and resistance tolerances for the effective voltage and the effective resistance driven by the external drivers at the drain, source, and gate terminals of the MOSFET. This may avoid convergence issues over minute driver variations in the particular timestamp.

In an embodiment, the method (200) may include configuring the MOSFET when the drain and gate terminals of the MOSFET are shorted. The MOSFET may be a n-type MOSFET or a p-type MOSFET.

The method (200) described herein may be implemented in software, hardware, or a combination thereof, in different embodiments. In addition, the order of steps in methods can be changed, and various elements may be added, reordered, combined, omitted, or otherwise modified. All examples described herein are presented in a non-limiting manner. Various modifications and changes can be made as would be obvious to a person skilled in the art having benefit of this disclosure. Many variations, modifications, additions, and improvements are possible. These and other variations, modifications, additions, and improvements can fall within the scope of embodiments as defined in the claims that follow.

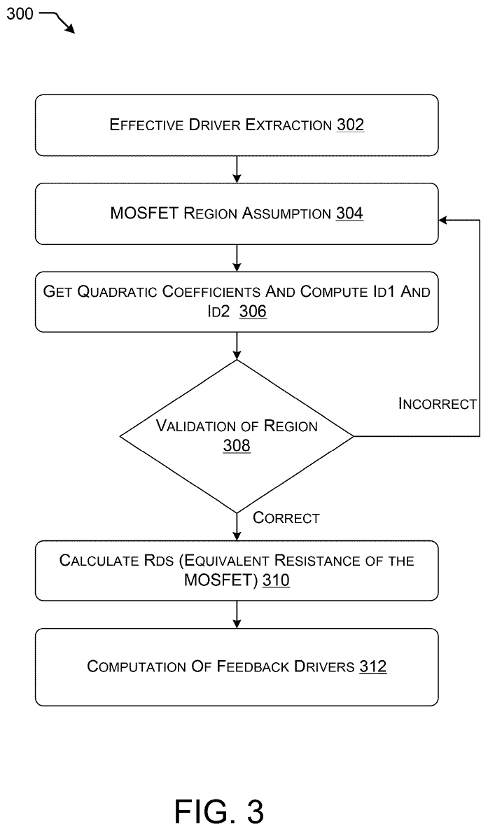

FIG. 3 illustrates a flow chart (300) depicting an evaluation flow of a MOSFET model, in accordance with an embodiment of the present disclosure.

With reference to FIG. 3, at 302, an Analog net including a Thevenin voltage and a Thevenin resistance at drain, source, and gate terminals of a MOSFET may be established. In response to establishing the Analog net, effective voltages and effective resistances may be extracted from the drain, source, and gate terminals of the MOSFET.

At 304, 306, and 308, initially, the MOSFET may be assumed to be in a saturation region, and respective quadratic equation may be solved to obtain two roots which represent the drain to source MOSFET currents ID1 and ID2 as solution using a fast quadratic solver. Saturation region conditions may be validated by calculating a drain to source MOSFET voltage and a gate to source MOSFET voltage with respect to new roots ID1 and ID2. The root satisfying MOSFET operating region may be determined as the drain to source MOSFET current.

If both roots fail to satisfy the saturation region, the MOSFET may be assumed to be in a linear region and respective quadratic expression may be evaluated to obtain the roots ID1 and ID2. Linear region conditions may be validated by calculating the drain to source MOSFET voltage and the gate to source MOSFET voltage with respect to the new roots ID1 and ID2. The root satisfying MOSFET operating region may be determined as the drain to source MOSFET current.

If the calculated roots fail to satisfy both regions i.e., the saturation region and the linear region, the MOSFET region may be determined as a cutoff region. In this case body diode expression may be evaluated and the drain to source MOSFET current in the cutoff region may be evaluated.

At 310, based on the validation of the region conditions, the drain to source MOSFET resistance may be calculated to balance the Kirchoff's voltage law based on the determined current drain to source MOSFET current and the drain to source MOSFET voltage.

At 312, feedback drivers from the MOSFET onto the Analog net at the drain, source, and gate terminals of the MOSFET may be evaluated as effective resistances and effective voltages by considering all calculated effective voltages and the effective resistances from the Analog net.

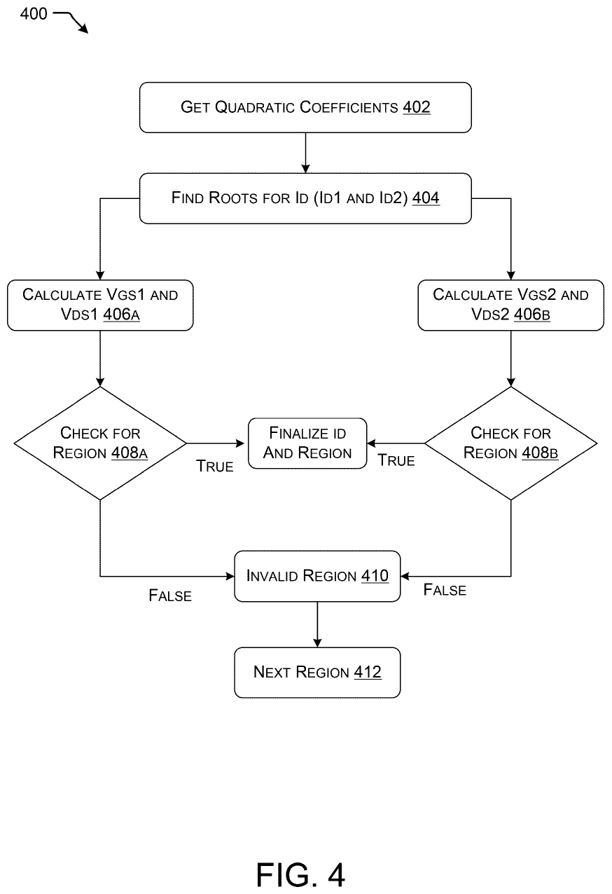

FIG. 4 illustrates a flow chart (400) depicting a process for determining a region of operation of a MOSFET using a fast quadratic solver, in accordance with an embodiment of the present disclosure.

With reference to FIG. 4, at 402, quadratic equations or quadratic coefficients which satisfy both Kirchoff's volage and current laws and MOSFET equations may be obtained.

At 404, roots of the quadratic equation for a region of operation of MOSFET may be determined using a fast quadratic solver. The roots may represent the drain to source MOSFET currents ID1 and ID2.

At 406a and 406b, drain to source MOSFET voltages V_{ds1}, V_{ds2} and gate to source MOSFET voltages V_{gs1}, V_{gs2} may be calculated with respect to new roots ID1 and ID2.

At 408a and 408b, region conditions may be validated based on the drain to source MOSFET voltages V_{ds1}, V_{ds2} and gate to source MOSFET voltages V_{gs1}, V_{ds2} to determine the drain to source MOSFET current I_{d}.

At 410 and 412, if the region conditions are not satisfied, the region of operation of the MOSFET may be considered invalid and a next region may be checked and validated to determine the drain to source MOSFET current I_{d}.

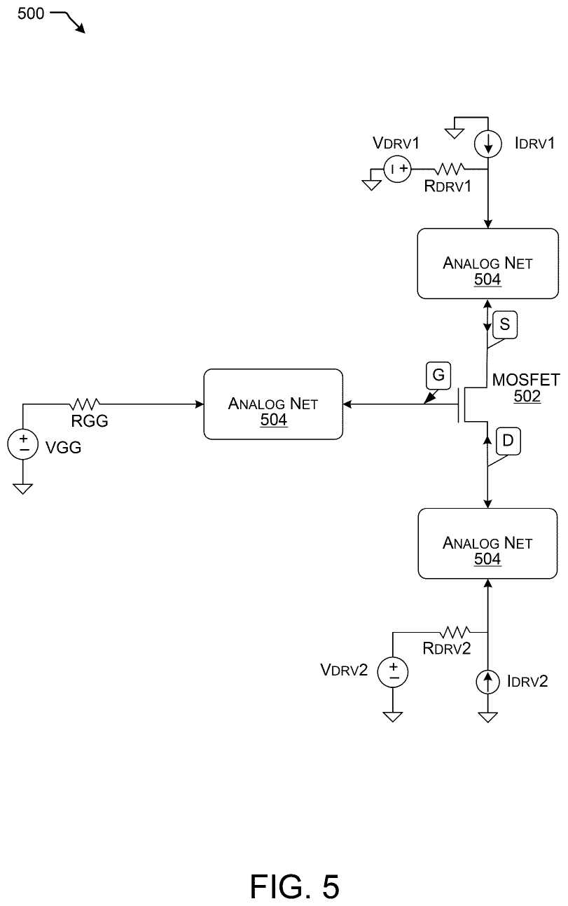

FIG. 5 illustrates a schematic representation depicting a MOSFET model (500), in accordance with an embodiment of the present disclosure.

With reference to FIG. 5, in the MOSFET model (500), an Analog net (504) including a Thevenin voltage and a Thevenin resistance at drain, source, and gate terminals of a MOSFET (502) may be established. The MOSFET model (500) may be a real-number MOSFET model that uses System Verilog user-defined nettypes and a fast quadratic solver for solving MOSFET equations, nodal voltages, and branch currents complying with Kirchhoff's current and voltage laws. The MOSFET model (500) may perform computations with a faster convergence rate than the conventional Simulation Program with Integrated Circuit Emphasis (SPICE) models, Verilog-A Verilog-AMS models, without losing significant accuracy. This may accelerate a functional verification cycle of mixed-signal designs involving the MOSFETs (502) in critical design path, and help in achieving a robust and bug-free mixed signal electronic design.

It will be apparent to those skilled in the art that the structure of the disclosure may be provided using some or all of the mentioned features and components without departing from the scope of the present disclosure. While various embodiments of the present disclosure have been illustrated and described herein, it will be clear that the disclosure is not limited to these embodiments only. Numerous modifications, changes, variations, substitutions, and equivalents will be apparent to those skilled in the art, without departing from the spirit and scope of the disclosure, as described in the claims.

The present disclosure provides a system and a method for efficiently implementing a real-number System Verilog model of a MOSFET for accelerated mixed-signal functional verification.

The present disclosure establishes an Analog net including a Thevenin voltage and a Thevenin resistance at drain, source, and gate terminals of a MOSFET.

The present disclosure computes drain to source MOSFET current, drain to source MOSFET voltage, and drain to source MOSFET resistance by extracting effective voltages and effective resistances from the drain, source, and gate terminals of the MOSFET.

The present disclosure provides feedback drivers of the drain to source MOSFET current in terms of a drive voltage and a drive resistance to the Analog net.

The present disclosure attains a circuit convergence in real-time through an event-driven mechanism at a particular timestamp.

The present disclosure performs computations with a faster convergence rate than conventional models, without losing significant accuracy.

The present disclosure accelerates a functional verification cycle of mixed-signal designs involving MOSFETs in a critical design path, and helps in achieving a robust and bug-free mixed signal electronic design.

The present disclosure determines MOSFET's operating point accurately in one iteration when used in a single MOSFET circuit and fewer (less than 20) iterations for complex designs.

The present disclosure converges within few iterations at a single timestep and improves simulation speed.

We claim:

1. A computer-implemented method for implementing a real-number System Verilog model of a Metal-Oxide-Semiconductor Field-Effect Transistor (MOSFET) for accelerated mixed-signal functional verification, comprising:
establishing, by a system, an Analog net comprising a Thevenin voltage and a Thevenin resistance at drain, source, and gate terminals of a MOSFET;
extracting, by the system, effective voltages and effective resistances from the drain, source, and gate terminals of the MOSFET;
establishing, by the system, a fast quadratic solver to compute drain to source MOSFET current, drain to source MOSFET voltage, and drain to source MOSFET resistance;
providing, by the system, feedback of the drain to source MOSFET current in terms of a drive voltage and a drive resistance to the Analog net; and
attaining, by the system, a circuit convergence in real-time through an event-driven mechanism at a particular timestamp.

2. The computer-implemented method as claimed in claim 1, wherein establishing, by the system, the Analog net comprising the Thevenin voltage and the Thevenin resistance at the drain, source, and gate terminals of the MOSFET comprises:
implementing, by the system, the Analog net using a user defined net-type and user defined resolution function for evaluation of the Thevenin voltage and the Thevenin resistance at the drain, source, and gate terminals of the MOSFET; and
interconnecting, by the system, each of the drain, source, and gate terminals of the MOSFET to other MOSFETs or electrical components.

3. The computer-implemented method as claimed in claim 1, wherein extracting, by the system, the effective voltages and the effective resistances from the drain, source, and gate terminals of the MOSFET comprises:
evaluating, by the system, the effective voltages and the effective resistances driven by external drivers at the drain, source, and gate terminals of the MOSFET using Thevenin equations and the drive voltage and the drive resistance driven to the Analog net from the MOSFET; and
determining, by the system, that the effective voltages and the effective resistances driven by the external drivers at the drain, source, and gate terminals of the MOSFET is within specified voltage and resistance tolerances.

4. The computer-implemented method as claimed in claim 1, wherein establishing, by the system, a fast quadratic solver to compute the drain to source MOSFET current, the drain to source MOSFET voltage, and the drain to source MOSFET resistance comprises:
computing, by the system, nodal voltages at the drain, source, and gate terminals of the MOSFET for the computed effective voltages and the drain to source MOSFET current by calculating a drain to source voltage and a gate to source voltage for the drain to source MOSFET current, wherein the drain to source MOSFET current is assumed zero at a first iteration of a first time-step.

5. The computer-implemented method as claimed in claim 4, further comprising computing, by the system, the drain to source MOSFET current in presently satisfied regions of operation of the MOSFET, based on the calculated drain to source voltage and the gate to source voltage of the MOSFET, by calculating roots of a quadratic equation for a selected region of operation of the MOSFET, wherein the quadratic equation is formulated by using at least one of: a Kirchoff's voltage law, a current law, or a drain to source MOSFET current equation for the selected region of operation of the MOSFET.

6. The computer-implemented method as claimed in claim 5, further comprising:
computing, by the system, a drain to source MOSFET voltage and a gate to source MOSFET voltage using the calculated roots of the quadratic equations; and
re-validating, by the system, the selected region of operation of the MOSFET by checking MOSFET operating region conditions, and using the result to select an appropriate drain to source MOSFET current from the two roots of the quadratic equation.

7. The computer-implemented method as claimed in claim 6, further comprising:
evaluating, by the system, the drain to source MOSFET current in other regions of operation if the calculated drain to source MOSFET current fails to satisfy previously satisfied MOSFET operating region conditions.

8. The computer-implemented method as claimed in claim 7, further comprising:
evaluating, by the system, a MOSFET body diode current, in response to the evaluated region of operation being a cutoff region, using numerical iterative approximations comprising diode equations.

9. The computer-implemented method as claimed in claim 1, wherein driving, by the system, the feedback of drain to source MOSFET current in terms of the drive voltage and the drive resistance to the Analog net comprises:
determining, by the system, an effective drain to source MOSFET resistance by using the drain to source MOSFET current and the drain to source MOSFET voltage; and
determining, by the system, drive voltages and drive resistances for each of the drain, source, and gate terminals of the MOSFET by using the effective drain to source MOSFET resistance, and effective voltage and resistance of external drivers at other terminals of the MOSFET.

10. The computer-implemented method as claimed in claim 1, wherein attaining, by the system, the circuit convergence in real-time comprises:
re-adjusting, by the system, by dynamically using the event-driven mechanism, the drain to source MOSFET current, the drain to source MOSFET voltage, and the drain to source MOSFET resistance based on a change in the Thevenin voltage and the Thevenin resistance at the drain, source, and gate terminals of the MOSFET in real-time at the particular timestamp.

11. The computer-implemented method as claimed in claim 1, wherein the MOSFET comprises one of: an n-type MOSFET or a p-type MOSFET.

12. The computer-implemented method as claimed in claim 1, comprising configuring, by the system, the MOSFET when the drain and gate terminals of the MOSFET are in a short circuit condition.

13. A system for implementing a real-number System Verilog model of a Metal-Oxide-Semiconductor Field-Effect Transistor (MOSFET) for accelerated mixed-signal functional verification, the system comprising:
a processor; and
a memory operatively coupled to the processor, wherein the memory comprises processor executable instructions which, when executed by the processor, cause the processor to:
establish an Analog net comprising a Thevenin voltage and a Thevenin resistance at drain, source, and gate terminals of a MOSFET;
extract effective voltages and effective resistances from the drain, source, and gate terminals of the MOSFET by external drivers;
compute drain to source MOSFET current, drain to source MOSFET voltage, and drain to source MOSFET resistance based on the extraction;
provide feedback of the drain to source MOSFET current in terms of a drive voltage and a drive resistance to the Analog net; and
attain a circuit convergence in real-time through an event-driven mechanism at a particular timestamp.

14. The system as claimed in claim 13, wherein the Analog net is established as an interconnection between a plurality of system components of an electrical circuit and the MOSFET.

15. The system as claimed in claim 13, wherein the processor is configured to compute the drain to source MOSFET current, the drain to source MOSFET voltage, and the drain to source MOSFET resistance by using a fast quadratic solver.

16. The system as claimed in claim 13, wherein the feedback of the drain to source MOSFET current is provided in terms of the drive voltage and the drive resistance to the Analog net by satisfying Kirchoff's voltage and current laws.

17. The system as claimed in claim 13, wherein the processor is configured to evaluate a driver strength at the drain, source, and gate terminals of the MOSFET for specified tolerance ranges.
